(19) United States
(12) Patent Application Publication
(10) Pub. No.: US 2025/0299937 A1
(43) Pub. Date: Sep. 25, 2025

(54) CRYOGENIC MOISTURE TRAP FOR IMPROVED ETCH AND PARTICLE REDUCTION

(71) Applicant: Applied Materials, Inc., Santa Clara, CA (US)

(72) Inventors: Hao WANG, Livermore, CA (US); Zhepeng CONG, San Jose, CA (US)

(21) Appl. No.: 18/615,421

(22) Filed: Mar. 25, 2024

(51) Int. Cl. H01J 37/32

(52) U.S. Cl. CPC H01J 37/32871; H01J 37/32834; H01J 37/3288; H01J 2237/002

(57) ABSTRACT

A moisture trap for use with a semiconductor processing chamber is described. The moisture trap is utilized during preventative maintenance of the processing chamber to remove moisture from the processing chamber. The moisture trap is attached to an exhaust line of the processing chamber and includes a body having an inner surface that forms a cavity for the moisture to condense and freeze. A cryogenic coil is disposed around the body of the moisture trap. A valve is disposed between the body of the moisture trap and the exhaust line and is opened during preventative maintenance.

### BACKGROUND

### Field

Embodiments described herein generally relate to semiconductor device fabrication. More specifically, embodiments of the present disclosure relate to apparatus for removing moisture from a semiconductor processing chamber.

### Description of the Related Art

In fabrication of an integrated circuit, prior to an epitaxial deposition process, a preclean process is performed on a semiconductor substrate. The substrate may be processed using one or more oxide etching processes. The oxide etching processes includes some combination of HF, NH₃, NH₄F, SiO₂ precursors. Vaporized H₂O may also be used as a carrier gas during formation of an etchant. The etchant reacts with SiO₂ to form byproducts that can be sublimated away after the initial reaction. However, water (H₂O) is also generated during etching of the substrate and may build up within a process volume of a pre-clean chamber.

Mechanical pumps are not generally adequate to exhaust H₂O from the pre-clean chamber. The trapped moisture can therefore condense on an internal surface of the pre-clean chamber, especially at relatively low temperature points. Moisture often accumulates on the backside of the substrate, the lower portion of the substrate support pedestal, and chamber sidewalls. The increase in moisture within the process chamber eventually causes accumulation of byproducts and particles within the process chamber. The etch rate of SiOₓ and etch uniformity may also be negatively affected.

The moisture is currently removed from the process chamber using by opening the chamber during preventative maintenance. Baking and conditioning are then utilized to remove accumulation effects of byproducts and particles. The effect of the moisture buildup also prolongs maintenance procedures as the process chamber may have to be run many times before stable conditions within the process chamber are reached, if the chamber was opened during preventative maintenance.

Frequent purging and heating of the process chamber only serves to temporarily reduce the moisture level, but is undesirable as it increases the amount of time required for chamber maintenance.

Therefore, there is a need for apparatus and methods of removing moisture from a process chamber without opening the process chamber.

### SUMMARY

Embodiments of the present disclosure provide an apparatus for regulating moisture levels within a semiconductor processing chamber. In at least one embodiment, the apparatus includes a moisture trap body. The moisture trap has an outer surface, an inner surface, a cavity formed by the inner surface, and a first fluid passage disposed through the outer surface to the inner surface. The apparatus further includes one or more inner films lining the inner surface, a cryogenic coil disposed around the moisture trap body, and an outer casing disposed around the cryogenic coil.

Another embodiment of the present disclosure provides a process chamber for processing a semiconductor device. The process chamber is equipped to regulate moisture levels within the process chamber. The process chamber includes a chamber body forming an interior volume, a substrate support disposed within the interior volume, an exhaust opening fluidly coupled to the interior volume, an exhaust line coupled to the exhaust opening, and a moisture trap coupled to the exhaust line. The moisture trap includes a body having: an outer surface, an inner surface, a cavity formed by the inner surface, and a first fluid passage extending from the inner surface to the exhaust line. The moisture trap further includes a cryogenic coil disposed around the moisture trap body and an outer casing disposed around the cryogenic coil.

Another embodiment of the present disclosure provides a method of performing preventative maintenance on a semiconductor processing chamber. The method includes opening a valve on a moisture trap, exhausting one or more fluid from the semiconductor processing chamber through an exhaust line, flowing a cryogenic fluid through a cryogenic coil within the moisture trap, and condensing and freezing moisture from the exhaust line onto an inner surface of the moisture trap.

### BRIEF DESCRIPTION OF THE DRAWINGS

So that the manner in which the above recited features of embodiments of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates a schematic top view of a multi-chamber processing system, according to embodiments of the present disclosure.

FIG. 2 is a cross-sectional view of the pre-clean system from the multi-chamber processing system of FIG. 1, according to one embodiment.

FIG. 3 illustrates a moisture trap for use in the exhaust line of the pre-clean system of FIG. 2, according to one embodiment.

FIG. 4 illustrates a moisture trap for use in the exhaust line of the pre-clean system of FIG. 2, according to another embodiment.

FIG. 5 is a flow diagram of a method of using the moisture traps of FIG. 3 or FIG. 4, according to embodiments of the present disclosure.

FIG. 6 illustrates a flow diagram of a method of regenerating a moisture trap for continuous use, according to embodiments of the present disclosure.

To facilitate understanding, identical reference numerals have been used, where possible, to designate identical elements that are common to the figures. It is contemplated that elements and features of one embodiment may be beneficially incorporated in other embodiments without further recitation. It is contemplated that elements disclosed in some embodiments may be beneficially utilized on other implementations without specific recitation.

### DETAILED DESCRIPTION

Embodiments described herein generally relate to semiconductor device fabrication. More specifically, embodiments of the present disclosure relate to apparatus for removing moisture from a semiconductor processing chamber.

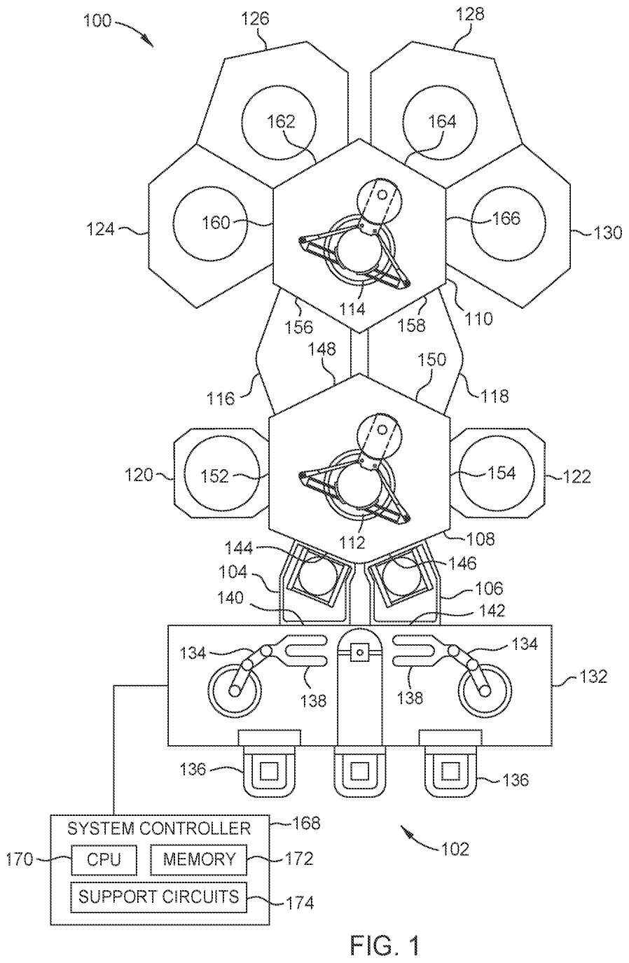

FIG. 1 is a schematic top view of a multi-chamber processing system 100, according to one or more embodiments of the present disclosure. The multi-chamber processing system 100 generally includes a factory interface 102, load lock chambers 104, 106, transfer chambers 108, 110 with respective transfer robots 112, 114, holding chambers 116, 118, and processing chambers 120, 122, 124, 126, 128, 130. As detailed herein, substrates in the multi-chamber processing system 100 can be processed in and transferred between the various chambers without exposing the substrates to an ambient environment exterior to the processing system 100. For example, the substrates can be processed in and transferred between the various chambers maintained at a low pressure (e.g., less than or equal to about 300 Torr) or vacuum environment without breaking the low pressure or vacuum environment among various processes performed on the substrates in the processing system 100. Accordingly, the multi-chamber processing system 100 may provide for an integrated solution for some processing of substrates.

In the illustrated example of FIG. 1, the factory interface 102 includes a docking station 132 and factory interface robots 134 to facilitate transfer of substrates. The docking station 132 is adapted to accept one or more front opening unified pods (FOUPs) 136. In some examples, each factory interface robot 134 generally includes a blade 138 disposed on one end of the respective factory interface robot 134 adapted to transfer the substrates from the factory interface 102 to the load lock chambers 104, 106.

The load lock chambers 104, 106 have respective ports 140, 142 coupled to the factory interface 102 and respective ports 144, 146 coupled to the transfer chamber 108. The transfer chamber 108 further has respective ports 148, 150 coupled to the holding chambers 116, 118 and respective ports 152, 154 coupled to processing chambers 120, 122. Similarly, the transfer chamber 110 has respective ports 156, 158 coupled to the holding chambers 116, 118 and respective ports 160, 162, 164, 166 coupled to processing chambers 124, 126, 128, 130. The ports 144, 146, 148, 150, 152, 154, 156, 158, 160, 162, 164, 166 can be, for example, slit valve openings with slit valves for passing substrates therethrough by the transfer robots 112, 114 and for providing a seal between respective chambers to prevent a gas from passing between the respective chambers. Generally, any port is open for transferring a substrate therethrough. Otherwise, the port is closed.

The load lock chambers 104, 106, transfer chambers 108, 110, holding chambers 116, 118, and processing chambers 120, 122, 124, 126, 128, 130 may be fluidly coupled to a gas and pressure control system. The gas and pressure control system can include one or more gas pumps (e.g., turbo pumps, cryo-pumps, roughing pumps), gas sources, various valves, and conduits fluidly coupled to the various chambers. In operation, a factory interface robot 134 transfers a substrate from a FOUP 136 through a port 140 or 142 to a load lock chamber 104 or 106. The gas and pressure control system then pumps down the load lock chamber 104 or 106. The gas and pressure control system further maintains the transfer chambers 108, 110 and holding chambers 116, 118 with an interior low pressure or vacuum environment (which may include an inert gas). Hence, the pumping down of the load lock chamber 104 or 106 facilitates passing the substrate between, for example, the atmospheric environment of the factory interface 102 and the low pressure or vacuum environment of the transfer chamber 108.

With the substrate in the load lock chamber 104 or 106 that has been pumped down, the transfer robot 112 transfers the substrate from the load lock chamber 104 or 106 into the transfer chamber 108 through the port 144 or 146. The transfer robot 112 is then capable of transferring the substrate to and/or between any of the processing chambers 120, 122 through the respective ports 152, 154 for processing and the holding chambers 116, 118 through the respective ports 148, 150 for holding to await further transfer. Similarly, the transfer robot 114 is capable of accessing the substrate in the holding chamber 116 or 118 through the port 156 or 158 and is capable of transferring the substrate to and/or between any of the processing chambers 124, 126, 128, 130 through the respective ports 160, 162, 164, 166 for processing and the holding chambers 116, 118 through the respective ports 156, 158 for holding to await further transfer. The transfer and holding of the substrate within and among the various chambers can be in the low pressure or vacuum environment provided by the gas and pressure control system.

The processing chambers 120, 122, 124, 126, 128, 130 can be any appropriate chamber for processing a substrate. In some examples, the processing chamber 120 can be capable of performing an etch process, the processing chamber 122 can be capable of performing a cleaning process, and the processing chambers 124, 126, 128, 130 can be capable of performing respective deposition processes.

A system controller 168 is coupled to the multi-chamber processing system 100 for controlling the multi-chamber processing system 100 or components thereof. For example, the system controller 168 may control the operation of the multi-chamber processing system 100 using a direct control of the chambers 104, 106, 108, 110, 116, 118, 120, 122, 124, 126, 128, 130 of the processing system multi-chamber 100 or by controlling controllers associated with the chambers 104, 106, 108, 110, 116, 118, 120, 122, 124, 126, 128, 130. In operation, the system controller 168 enables data collection and feedback from the respective chambers to coordinate performance of the processing system 100.

The system controller 168 generally includes a central processing unit (CPU) 170, memory 172, and support circuits 174. The CPU 170 may be one of any form of a general-purpose processor that can be used in an industrial setting. The memory 172, or non-transitory computer-readable medium, is accessible by the CPU 170 and may be one or more of memory such as random access memory (RAM), read only memory (ROM), floppy disk, hard disk, or any other form of digital storage, local or remote. The support circuits 174 are coupled to the CPU 170 and may comprise cache, clock circuits, input/output subsystems, power supplies, and the like. The various methods disclosed herein may generally be implemented under the control of the CPU 170 by the CPU 170 executing computer instruction code stored in the memory 172 (or in memory of a particular processing chamber) as, for example, a software routine. When the computer instruction code is executed by the CPU 170, the CPU 170 controls the chambers to perform processes in accordance with the various methods.

Other processing systems can be in other configurations. For example, more or fewer processing chambers may be coupled to a transfer apparatus. In the illustrated example, the transfer apparatus includes the transfer chambers 108, 110 and the holding chambers 116, 118. In other examples, more or fewer transfer chambers (e.g., one transfer chamber) and/or more or fewer holding chambers (e.g., no holding chambers) may be implemented as a transfer apparatus in a processing system.

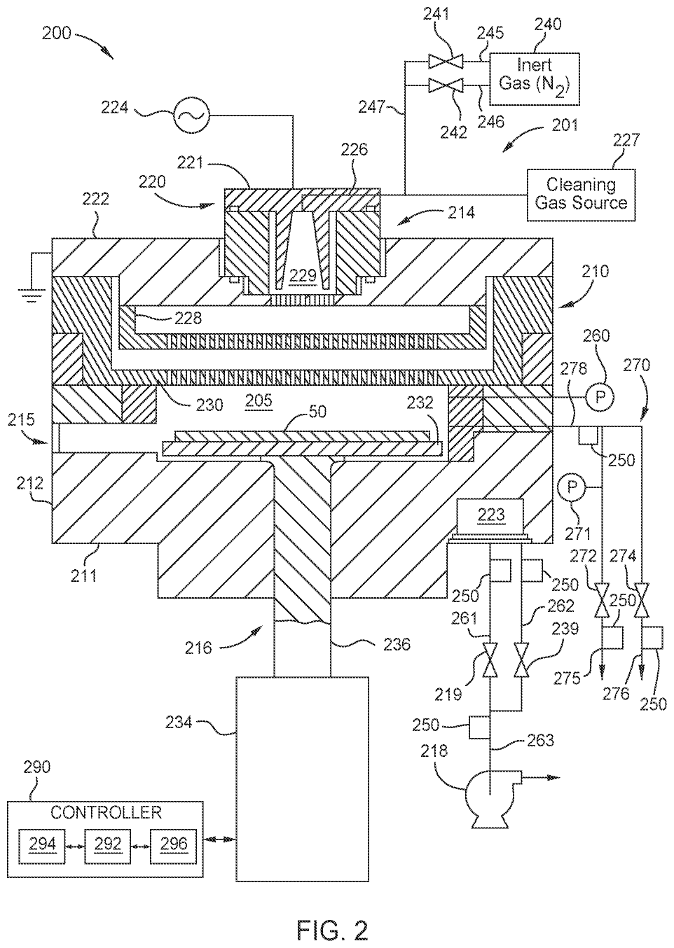

FIG. 2 is a cross-sectional view of a pre-clean system 200. The pre-clean system 200 may be one or more of the processing chambers 120, 122, 124, 126, 128, 130. The pre-clean system 200 includes a pre-clean chamber 201 (also referred to as a process chamber). The pre-clean chamber 201 includes a chamber body 210. The chamber body 210 includes a bottom 211, a lid assembly 214, and one or more chamber walls 212 connecting the bottom 211 with the lid assembly 214. The chamber body 210 can enclose an interior volume 205 of the pre-clean chamber 201.

The pre-clean chamber 201 further includes a substrate support assembly 216. The substrate support assembly 216 can include a substrate support 232, an actuator 234, and a shaft 236 connecting the actuator 234 with the substrate support 232. The substrate support 232 can be located in the interior volume 205 to support a substrate 50 during processing.

The chamber body 210 can further include a slit valve 215 to allow insertion and removal of a substrate 50 into and from the interior volume 205 of the pre-clean chamber 201. The pre-clean system 200 and multi-chamber processing system 100 can be configured to have a pressure in the interior volume 205 remain below a pressure in the transfer chamber 108 when the slit valve 215 is opened to prevent flow of gas and/or particles from the pre-clean chamber 201 to the transfer chamber 108 as described in further detail below.

The lid assembly 214 is disposed at an upper end of the chamber body 210. The lid assembly 214 can include a remote plasma source 220 for generating a plasma from cleaning gases provided to the remote plasma source 220. The cleaning gases can be provided from a cleaning gas source 227 through a gas inlet 226 of the pre-clean chamber 201. The cleaning gas source 227 can include a separate tank for each cleaning gas. In one embodiment, the cleaning gases from the cleaning gas source 227 can include one or more of hydrogen (H₂), nitrogen trifluoride (NF₃), and ammonia (NH₃). The remote plasma source 220 can include a first electrode 221 and a second electrode 222. The first electrode 221 can be spaced apart from the second electrode 222. The remote plasma source 220 can include a plasma-generating volume 229 positioned between the first electrode 221 and the second electrode 222.

The pre-clean system 200 can include a radio frequency (RF) power source 224. The RF power source 224 can be connected to the first electrode 221. The second electrode 222 can be connected to electrical ground to serve as a return path for the RF power when the plasma is generated in the volume 229. The RF power source 224 can be used to generate a plasma of the cleaning gases inside plasma-generating volume 229 when the cleaning gases are provided to the remote plasma source 220.

The lid assembly 214 can further include a blocker plate 228 and a showerhead 230 for distributing gas and/or plasma to the interior volume 205 of the pre-clean chamber 201. The blocker plate 228 can be positioned between the remote plasma source 220 and the showerhead 230. One or more additional showerheads 230 may also be utilized. The blocker plate 228 can receive plasma and/or gas discharged from the remote plasma source 220. In some embodiments, one or more gases may be provided directly to the blocker plate 228 or showerhead 230 allowing the remote plasma source 220 to be bypassed.

The pre-clean system 200 can further include an inert gas source 240 connected to the pre-clean chamber 201. In one embodiment, the inert gas source 240 includes nitrogen, but in other inert gases (e.g., argon) may also be used. The inert gas can be used to pressurize the interior volume 205 of the pre-clean chamber 201 after a pre-clean process is performed on the substrate 50 and/or before a new substrate 50 is transferred into the pre-clean chamber 201. The pre-clean system 200 can include a pressure sensor 260 configured to measure a pressure of the interior volume 205 of the pre-clean chamber 201.

The inert gas source 240 can be connected to the gas inlet 226 of the process chamber through a first supply line 245 or a second supply line 246 of the pre-clean system 200. The first supply line 245 and the second supply line 246 can be connected to the gas inlet 226 through a common supply line 247. The first supply line 245 and the second supply line 246 can be arranged to form parallel (i.e., alternative) paths relative to each other, so that gas can be supplied to the pre-clean chamber 201 through one of the supply lines without going through the other supply line.

The first supply line 245 can include a first supply valve 241 that can be opened to connect the first supply line 245 with the common supply line 247. The second supply line 246 can include a second supply valve 242 that can be opened to connect the second supply line 246 with the common supply line 247.

The pre-clean system 200 can further include a vacuum pump 218 configured to exhaust gas from the pre-clean chamber 201 through an exhaust port 223 of the pre-clean chamber 201. The vacuum pump 218 can be connected to the exhaust port 223 through a first exhaust line 261 or a second exhaust line 262 of the pre-clean system 200. The first exhaust line 261 and the second exhaust line 262 can be arranged to form parallel (i.e., alternative) paths relative to each other, so that gas can be exhausted from the pre-clean chamber 201 through one of the exhaust lines without going through the other exhaust line. The first exhaust line 261 and the second exhaust line 262 can be connected to the exhaust port 223 through a common exhaust line 263. The first exhaust line 261 can include a first exhaust valve 219 that can be opened to fluidly couple the first exhaust line 261 with the common exhaust line 263. The second exhaust line 262 can include a second exhaust valve 239 that can be opened to fluidly couple the second exhaust line 262 with the common exhaust line 263.

As introduced above, the substrate support assembly 216 includes the substrate support 232, the actuator 234, and the shaft 236 connecting the actuator 234 with the substrate support 232. The shaft 236 can extend through a centrally-located opening formed in the bottom 211 of the chamber body 210. The actuator 234 may be flexibly sealed to the bottom 211 of the chamber body 210 by bellows (not shown) that prevent vacuum leakage from around the shaft 236. The actuator 234 allows the substrate support 232 to be moved vertically within the chamber body 210 between a process position and a lower transfer position. The transfer position can be slightly below the opening of the slit valve 215 formed through one of the one or more walls 212 of the chamber body 210.

Although not shown, in some embodiments, an RF and/or DC bias can be coupled to the substrate support 232 to assist with directing the cleaning plasma toward the substrate 50.

The pre-clean system 200 can further include an auxiliary exhaust assembly 270. The auxiliary exhaust assembly 270 can include a first auxiliary exhaust line 275, a second auxiliary exhaust line 276, and a common auxiliary exhaust line 278. The auxiliary exhaust assembly 270 can further include a vacuum pump or other device for creating a negative pressure in the auxiliary exhaust assembly 270 lines relative to the interior volume 205 of pre-clean chamber 201, so that gas is exhausted from the interior volume 205 through the auxiliary exhaust assembly 270 when the valves of the auxiliary exhaust assembly 270 are opened.

The common auxiliary exhaust line 278 can be connected to the interior volume 205 of the pre-clean chamber 201. The first auxiliary exhaust line 275 and the second auxiliary exhaust line 276 can be connected to the interior volume 205 of the pre-clean chamber 201 through the common auxiliary exhaust line 278. The first auxiliary exhaust line 275 can include a first auxiliary exhaust valve 272 that can be opened to connect the first auxiliary exhaust line 275 with the common auxiliary exhaust line 278. The second auxiliary exhaust line 276 can include a second auxiliary exhaust valve 274 that can be opened to connect the second auxiliary exhaust line 276 with the common auxiliary exhaust line 278.

The first auxiliary exhaust valve 272 can be opened when a high pressure condition occurs. The first auxiliary exhaust line 275 can include a pressure sensor 271 to measure a pressure inside the first auxiliary exhaust line 275. Upon measuring a pressure above a given threshold (e.g., 800 Torr), the first auxiliary exhaust valve 272 can be opened to relieve pressure inside the interior volume 205. The pre-clean chamber 201 may be operated at either a low pressure (e.g., less than 100 Torr) or a high pressure (e.g., greater than 100 Torr) for the pre-clean process and substrate transfer.

The second auxiliary exhaust valve 274 can be opened when the slit valve 215 is opened, which allows gas to flow from the interior volume 205 and out the auxiliary exhaust assembly 270. The interior volume 205 of the pre-clean chamber 201 is generally considered to be less clean than the interior volume of the transfer chamber 108. Thus, gas should not flow from the interior volume 205 of the pre-clean chamber 201 to the interior volume of the transfer chamber 108. Opening the second auxiliary exhaust valve 274 when the slit valve 215 opens reduces the pressure in the interior volume 205 relative to the pressure in the interior volume of the transfer chamber 108 and gas flows from the interior volume of the transfer chamber 108 through the interior volume 205 of the pre-clean chamber 201 and out through the auxiliary exhaust assembly 270.

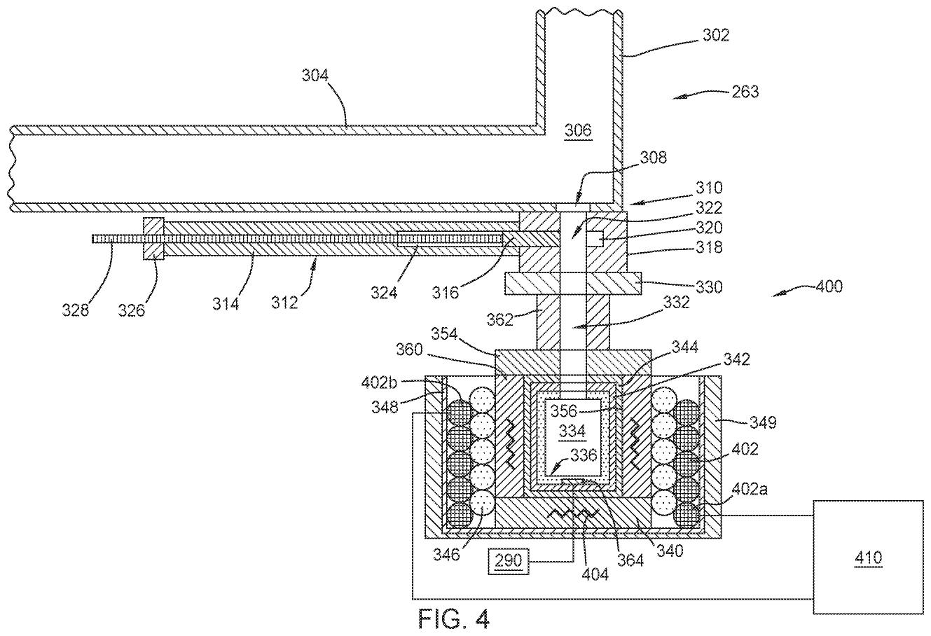

One or more moisture traps 250 are disposed on one or more of the exhaust lines 261, 262, 263, 278, 275, 276. The moisture traps 250 are disposed downstream of the pre-clean chamber 201, such that the moisture traps 250 are disposed outside of the chamber body 210. The moisture traps 250 are coupled to the side of the exhaust lines 261, 262, 263, 278, 275, 276. In some embodiments, there may be only one moisture trap 250. The moisture traps 250 connect to the exhaust lines 261, 262, 263, 278, 275, 276 at a point downstream from an exhaust port or an exhaust opening, such as the exhaust port 223, but upstream of an exhaust pump, such as the vacuum pump 218. In embodiments wherein the moisture traps 250 are configured to be used repeatedly over a long period of time, such as when utilizing an embodiment similar to the embodiment of FIG. 4, the moisture trap 250 is downstream of one or more valves, such as the exhaust valves 219, 239, 274. The moisture trap 250 may be positioned at a curve or bend in the exhaust lines 261, 262, 263, 278, 275, 276, such as at a joint in the exhaust lines 261, 262, 263, 278, 275, 276.

The pre-clean system 200 can also include a controller 290 for controlling processes within the pre-clean system 200 (FIG. 2) and other portions of the processing system 100 (FIG. 1). The controller 290 can be any type of controller used in an industrial setting, such as a programmable logic controller (PLC). The controller 290 includes a processor 292, a memory 294, and input/output (I/O) circuits 296. The controller 290 can further include one or more of the following components (not shown), such as one or more power supplies, clocks, communication components (e.g., network interface card), and user interfaces typically found in controllers for semiconductor equipment.

The memory 294 can include non-transitory memory. The non-transitory memory can be used to store the programs and settings described below. The memory 294 can include one or more readily available types of memory, such as read only memory (ROM) (e.g., electrically erasable programmable read-only memory (EEPROM), flash memory, floppy disk, hard disk, or random access memory (RAM) (e.g., non-volatile random access memory (NVRAM).

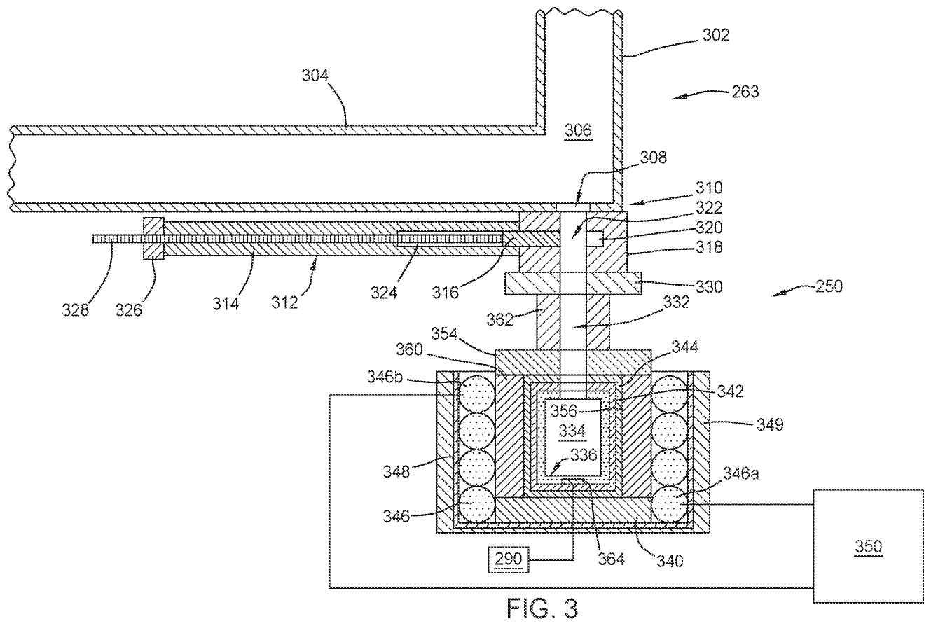

The processor 292 is configured to execute various programs stored in the memory 294, such as a program configured to execute the method 1000 described below in reference to FIG. 3. During execution of these programs, the controller 290 can communicate to I/O devices (e.g., sensors and actuators) through the I/O circuits 296. For example, during execution of these programs and communication through the I/O circuits, the controller 290 can control outputs (e.g., open and close valves) and receive information from feedback devices (e.g., feedback on the open/close state of valves), sensors, and other instrumentation in the pre-clean system 200 and other portions of the multi-chamber processing system 100.

The memory 294 can further include various operational settings used to control the pre-clean system 200 and other portions of the multi-chamber processing system 100. For example, the settings can include pressure settings for when a transition between slowly changing and more quickly changing the pressure in the interior volume 205 is made in the method 1000 as described below in reference to FIG. 3 among various other settings.

FIG. 3 illustrates the moisture trap 250 for use in an exhaust line, such as one or more of the exhaust lines 261, 262, 263, 278, 275, 276, of the pre-clean system of FIG. 2. The moisture trap 250 includes each of a body 340 (sometimes referred to as a moisture trap body). The moisture trap 250 also includes one or more films 342, 344 disposed within a cavity 334 of the body 340. A cryogenic coil 346 is disposed around at least a portion of the body 340. An outer casing 348 is disposed around the cryogenic coil.

The body 340 includes an outer surface 354 and an inner surface 356. The cavity 334 is formed by the inner surface 356. The cavity 334 may also be referred to as an interior volume of the moisture trap. The body 340 may have a honey-pot shape, such that a cross-section of the body 340 is generally circular. The body 340 has a narrower neck 362 that connects a main portion 360 of the body 340 to a flanged portion 330 of the body 340. The main portion 360 of the body may be generally cylindrical in shape. The neck 362 also has a generally cylindrical shape, but has a smaller diameter than the main portion 360 of the body 340. A first fluid passage 332 is disposed between the cavity 334 and the outer surface 354 of the flanged portion 330. The first fluid passage 332 fluidly connects the cavity 334 and the outer surface 354. The first fluid passage 332 aligns with, and is in fluid communication with, a second fluid passage 322 disposed through a valve 312. The first fluid passage 332 fluidly connects the cavity 334 to an exhaust line opening 308 within the sidewall of the common exhaust line 263.

The flanged portion 330 of the body 340 is configured to couple the body 340 to the valve 312 and the exhaust line, such as the common exhaust line 263. The flanged portion 330 includes a vacuum flange-fitting, such as an NW, KF, or QF flange. In instances where a KF flange is utilized, the KF flange is one of a 10 mm, 16 mm, 25 mm, 40 mm, or 50 mm flange. The flanged portion 330 has a generally cylindrical shape and has a larger diameter than the neck 362.

The body 340 is a heat sink and may be formed of a thermally conductive metal alloy, such as aluminum or stainless steel. The body 340 is at least partially exposed to the elements and therefore it is desirable to make the body 340 from a material which will not easily tarnish, oxidize, or interact with other materials. The walls of the body 340 have a thickness of about 0.15 mm to about 15 mm, such as about 0.2 mm to about 12 mm, such as about 0.3 mm to about 10 mm. The walls of the body 340 are thick enough to provide structural support to the moisture trap 250, but thin enough to enable rapid heat transfer between the inner surface 356 and the outer surface 362.

The one or more films 342, 344 includes a first film 344 and a second film 342. The first film 344 is a foil film or a plating that is disposed as a lining to the inner surface 356 of the body 340. The first film 344 acts as a self regulating material for heat conductivity and assists in distributing heating or cooling within the body 340. The first film 344 may be a foil or plating formed of one or a combination of a metal, a metalloid, a post-transition metal, or a metal alloy. The metal alloy may include each of metals, metalloids, and post-transition metals. In some embodiments, the first film 344 has a first thermal conductivity of greater than about 70 W/m-K, such as greater than about 75 W/m-K, such as greater than about 80 W/m-K. Indium foil may have a thermal conductivity of about 84 W/m-K. The first film 344 may be one or a combination of silver, gold, copper, aluminum nitride, silicon carbide, aluminum, tungsten, graphite, zinc, lead alloy, tin, cadmium, and indium. Lead alloys, tin, cadmium, indium, gold, aluminum, and tungsten foils may be used due to their high thermal conductivity, high malleability, and resistance to oxidation. In some embodiments, indium foil is utilized.

The second film 342 may be a protective film to prevent reaction of the first film 344 with any precursor gases, other than water vapor, that enter the cavity 334. The second film 342 has a second thermal conductivity of greater than about 70 W/m-K, such as greater than about 75 W/m-K, such as greater than about 80 W/m-K. The second film 342 is also a foil or metal plating formed from a metal, a metalloid, a post-transition metal, or a metal alloy. In some embodiments, the second film 342 includes one or a combination of silver, gold, copper, aluminum nitride, silicon carbide, aluminum, tungsten, graphite, zinc, lead alloy, tin, cadmium, and indium. Lead alloys, tin, cadmium, indium, gold, aluminum, and tungsten foils may be used due to their high thermal conductivity, high malleability, and resistance to oxidation. In some embodiments, indium foil is utilized.

The cryogenic coil 346 is wrapped around the outer surface 354 of the body 340, such as around the outer surface 354 of the main portion 360 of the body 340. The inner diameter of the cryogenic coil 346 may be just slightly larger than the outer diameter of the main portion 360, such as less than 1.5 mm larger, such as less than 1.0 mm larger. The cryogenic coil 346 is configured to be able to reach temperatures of about −10° C. to about −210° C., such as about −20° C. to about −200° C., such as about −20° C. to about −190° C. In some embodiments, a liquid gas, such as liquid helium or liquid nitrogen, is configured to be circulated through the inside of the cryogenic coil 346. As the cryogenic coil 346 is run, a film, such as the film 336, may form on the inside surface 344 of the body 340, such as the inside surface of the second film 342. The cryogenic coil 346 may be coupled to a cryogenic liquid supply 350. The cryogenic liquid supply 350 is fluidly coupled to the cryogenic coil 346, such that a cryogenic fluid enters the cryogenic coil 346 at an opening 346a and exits the cryogenic coil 346 at an exit 346b. The cryogenic liquid supply 350 may be configured to supply cryogenic nitrogen or cryogenic helium.

An outer casing 348 is disposed around the cryogenic coil. The outer casing 348 may be a metal casing and helps provide support to the moisture trap 250 structure. The outer casing 348 may be made of an aluminum or stainless steel material. In some embodiments, the outer casing 348 is formed of a stainless steel material since stainless steel has a lower thermal conductivity than aluminum. The thermal conductivity of the outer casing 348 may be about 8 W/m-K to about 30 W/m-K, such as about 10 W/m-K to about 25 W/m-K, such as 12 W/m-K to about 20 W/m-K. An insulation layer 349 may be disposed around the outer surface of the outer casing 348 or attached to the outer surface of the outer casing 348 and is configured to reduce the amount of heat transfer between the moisture trap 250 and the outside environment. The insulation layer 349 may be formed of one or more foams, one or more ceramics, or vacuum insolation. The thermal conductivity of the insulation layer 349 is less than about 0.1 W/mK, such as less than about 0.05 W/mK, such as less than about 0.04 W/mK, such as less than about 0.03 W/mK.

The moisture trap 250 of FIG. 3 may be configured to be screwed and unscrewed from one or both of the valve 312 and the common exhaust line 263. There may be a threaded connection (not shown) between the flanged portion 330 of the moisture trap 250 and one or more of the valve 312 and the common exhaust line 263.

The moisture trap 250 is coupled to an outer surface of the common exhaust line 263. In some embodiments, such as the embodiments of FIG. 3 and FIG. 4, the moisture trap 250 is disposed on a bend of the common exhaust line 263, such as at a corner 310 of a joint in the common exhaust line 263. The moisture trap 250 is between an upstream portion 302 of the common exhaust line 263 and a downstream portion 304 of the common exhaust line 263. The upstream portion 302 extends towards the pre-clean system 200. The downstream portion 304 extends towards a vacuum pump, such as the vacuum pump 218. The exhaust line opening 308 puts the cavity 334 in fluid communication with an exhaust line volume 306.

The valve 312 is coupled to the outer surface 362 of the body 360 at the flange 330. The valve 312 is also coupled to the outer surface of the common exhaust line 263 at the exhaust line opening 308 disposed through the sidewall of the common exhaust line 263. The valve 312 is a valve suitable for use under vacuum conditions and that is capable of forming a seal between the exhaust line volume 306 and the cavity 334. The valve 312 may be one of a bell valve, an angle valve, or a gate valve. In the embodiment of FIG. 3, the valve 312 is a gate valve.

The valve 312 includes each of a valve body 314, the second fluid passage 322 disposed through the valve body 314 and aligned with the first fluid passage 332, and a gate 316 configured to be actuated to open and close the gate valve. The gate 316 may be actuated by turning a stem 328 that is fixed to the gate 316, such that when the stem 328 is turned using a nut 326, the gate 316 may be actuated between an open position (as seen in FIG. 3) or to a close position where the gate 316 blocks the second fluid passage 322 and creates a seal with a seat 320 on the other side of the second fluid passage 322. The seat 320 may be a divot or groove into which the gate 316 can be inserted to form a seal. The gate 316 may be actuated through a packing volume 324. The packing volume 324 may include one or more sealing rings, bushings, or glands. The nut 326 may be a nut configured to be turned with a wrench or may be replaced with a wheel or another component for rotating the stem 328.

A thermocouple 364 is disposed within the cavity 334. The thermocouple 364 may be disposed inside of one or both of the first film 344 and the second film 342. The thermocouple 364 is configured to enable temperature measurement inside of the moisture trap 250 and ensure the moisture trap 250 is operating as intended. Therefore, when the thermocouple 364 begins to measure a temperature that is greater than a predetermined value, the moisture trap 250 may be replaced. The temperature within the moisture trap 250 may increase as the moisture film 336 increases in thickness. The thermocouple 364 is coupled to a controller, such as the controller 290, so that the voltage difference can be measured and correlated back to a temperature within the moisture trap 250. In some embodiments, the thermocouple 364 may be disposed outside of the first film 344 or the second film 342, such as between the first film 344 and the inside surface 356 of the body 340. In some embodiments, the thermocouple 364 may be embedded inside of the body 340.

FIG. 4 illustrates another embodiment of a moisture trap 400 for use in an exhaust line, such as one or more of the exhaust lines 261, 262, 263, 278, 275, 276, of the pre-clean system of FIG. 2. The moisture trap 400 is capable of regenerating moisture that is trapped within the moisture trap 400, such that the moisture film 336 may be vaporized by heating up the moisture trap 400 and venting the moisture back out into the exhaust line volume 306. Heating of the moisture trap 400 can be accomplished using one or more heat sources coupled to the moisture trap body. The one or more heat sources may include one or both of a heated fluid coil 402 or resistive heating elements 404.

The heated fluid coil 402 is disposed between the outer casing 348 and the outer surface 354, such as between the outer casing 348 and the cryogenic coil 346. The heated fluid coil 402 is configured to receive a fluid from a fluid source 410. The fluid provided by the fluid source 410 and inside of the heated fluid coil 402 is at a temperature greater than the evaporation point of water within the cavity 334 of the moisture trap 400, such as greater than about 90° C., such as greater than about 110° C., such as greater than about 120° C. Although not limited to fluids included in the current disclosure, the fluid provided by the fluid source 410 may be water, oil, or propane.

Either in addition to or alternative to using the heated fluid coil 402, one or more resistive heating elements 404 may be disposed within the moisture trap 400. The one or more resistive heating elements 404 include a plurality of heating elements disposed within the body 340. Positioning the resistive heating elements 404 within the body enables for more rapid heating of any moisture within the cavity 334 since the resistive heating elements 404 are closer to the inner surface 356. The resistive heating elements 404 are coupled to a controller and/or a power source (not shown). In some embodiments, the resistive heating elements 404 are used in place of the heated fluid coil 402 and a resistive heating coil is wrapped around the cryogenic coil 346 and inside of the outer casing 348. It is envisioned that other types of heating devices may also be utilized, such as Peltier devices.

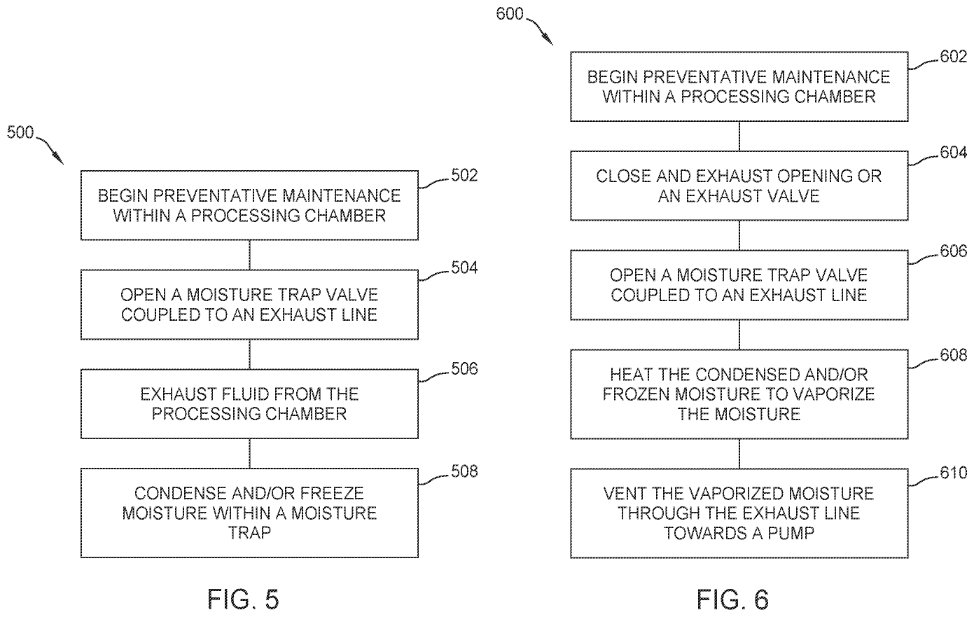

FIG. 5 is a flow diagram of a method 500 of using the moisture traps, such as the moisture trap 250 of FIG. 3 or the moisture trap 400 of FIG. 4. The method 500 is performed during preventative maintenance of a semiconductor processing chamber, such as the pre-clean system 200. The method 500 is a method of moisture removal from an inside volume of the processing chamber. Moisture is removed during the method 500 by creating a low vapor partial pressure within the exhaust lines, such as the exhaust lines 261, 262, 263, 278, 275, 276. The low vapor partial pressure assists in exhausting moisture from the inner volume of the processing chamber.

After equipping a process chamber with a moisture trap, moisture removal starts by beginning preventative maintenance within the processing chamber, such as a pre-clean chamber, during an operation 502. Preventative maintenance may include a series of purges and bakes within the processing chamber to remove unwanted byproducts.

Once preventative maintenance has begun, a moisture trap valve, such as the valve 312, is opened during an operation 504. The moisture trap valve may be opened by turning a nut and a stem, such as the nut 326 and the stem 328, to open a gate, such as the gate 316. The moisture trap is coupled to one or more exhaust lines. The moisture trap may be attached to a sidewall of one or more exhaust lines and aligned with an opening through a sidewall of the exhaust line. Once opened during the operation 504, the volume within the exhaust line and a volume within the moisture trap are in fluid communication.

After opening the moisture trap, fluid may be exhausted from the processing chamber during an operation 506. Fluid may be exhausted by purging the processing chamber with one or more inert gases. While fluid is being exhausted from the processing chamber, moisture within the moisture trap is condensed and frozen during an operation 508. Freezing the moisture within the moisture trap causes a low partial pressure of water within the exhaust line and improves the removal rate of moisture from the processing chamber. Moisture may be frozen by flowing a cryogenic fluid through a cryogenic coil, such as the cryogenic coil 346, around a body of the moisture trap. Therefore, the temperature within the moisture trap drops to less than a freezing point of water vapor, such as less than about 0° C. or less than about −20° C., such as about −20° C. to about −210° C., such as about −20° C. to about −190° C. The pressure within the cavity 334 is less than 2 Torr, such as less than 200 m Torr, such as less than 100 mTorr, such as less than 50 mTorr, such as less than 25 m Torr, such as less than 20 mTorr.

Once the water within the processing chamber has been reduced to a desired amount, the valve of the moisture trap is closed and the preventative maintenance procedure may continue until it is completed. When the moisture trap accumulates enough frozen water and is no longer able to function properly, the body of the moisture trap may be detached from the exhaust line by unscrewing the moisture trap from its connection with the closed valve. The moisture trap may then be replaced.

FIG. 6 illustrates a method 600 of regenerating a moisture trap for continuous use. In some embodiments, a moisture trap is utilized that is capable of regeneration, such that the built up water within the moisture trap is removed and the moisture trap can be utilized for a longer period of time before being replaced. The moisture trap 400 of FIG. 4 is one embodiment of a moisture trap capable of regeneration. The method 600 may be utilized after the method 500 of FIG. 5 has been performed multiple times or after each time the method 500 is performed.

During the method 600, preventative maintenance is begun within a processing chamber during an operation 602. The operation 602 is similar to the operation 502 of FIG. 5. After preventative maintenance has begun, an exhaust opening of the processing chamber, or an exhaust valve between the moisture trap and the exhaust opening, is closed during an operation 604. When performing both of the method 500 of FIG. 5 and the method 600 of FIG. 6 subsequent one another, the operation 604 is performed subsequent to operation 508. Closing one or more of the exhaust opening or an exhaust valve fluidly isolates the processing chamber from the moisture trap by blocking the fluid flow through the exhaust lines upstream of the moisture trap. Fluidly isolating the processing chamber from the moisture trap prevents regenerated vapor from flowing upstream into the processing chamber during the method 600.

After blocking upstream fluid flow, the moisture trap is opened by opening a valve, such as the valve 312, during an operation 606. The operation 606 is the same as the operation 504 of FIG. 5. After the valve is opened during operation 606, the cavity within the moisture trap is in fluid communication with the exhaust line and a downstream vacuum pump, but not with the interior volume of the processing chamber.

After opening the moisture trap valve, the moisture trap is heated using one or more heating devices, such as the heating devices 402, 404 of FIG. 4. The heating devices raise the temperature within the moisture trap to greater than about 100° C., such as greater than about 110° C., such as greater than about 120° C., such as greater than about 130° C. The pressure within the cavity 334 is less than 2 Torr, such as less than 200 mTorr, such as less than 100 mTorr, such as less than 50 mTorr, such as less than 25 mTorr, such as less than 20 mTorr. Heating the moisture trap causes the frozen moisture within the moisture trap to vaporize and be vented back into the exhaust line. A purge gas may be applied to the exhaust line to push the vaporized moisture downstream towards the vacuum pump during an operation 610. The vacuum pump may then remove the vaporized moisture.

In summary, a moisture trap for use in the exhaust lines of semiconductor processing chambers is described. The moisture trap may be utilized with epitaxial deposition pre-clean chambers that utilize etch processes that have water byproducts. The moisture trap improves the ability to remove moisture accumulated within the processing chambers and improves processing chamber health and production. The moisture trap may be disposable or capable of being regenerated. The moisture trap may be honey pot type trap and freezes moisture within an internal volume that is brought to near-cryogenic temperatures using a cryogenic coil that is disposed around at least a portion of the moisture trap body.

While the foregoing is directed to embodiments of the present disclosure, other and further embodiments of the disclosure may be devised without departing from the basic scope thereof, and the scope thereof is determined by the claims that follow.

We claim:

1. An apparatus for regulating moisture levels in a substrate processing chamber, comprising:
a moisture trap body comprising:
an outer surface;
an inner surface;
a cavity formed by the inner surface; and
a first fluid passage disposed through the outer surface to the inner surface;
a cryogenic coil disposed around the moisture trap body; and
an outer casing disposed around the cryogenic coil.

2. The apparatus of claim 1, further comprising:
a first film comprising one or a combination of a metal, a metalloid, a post-transition metal, or a metal alloy with a first thermal conductivity; and
a second film disposed on the inside of the first film, the second film having a second thermal conductivity.

3. The apparatus of claim 2, wherein the moisture trap body is a heat sink.

4. The apparatus of claim 1, further comprising a valve coupled to the outer surface and aligned with the first fluid passage.

5. The apparatus of claim 4, wherein the valve is a gate valve and further comprises:
a valve body;
a second fluid passage disposed through the valve body and aligned with the first fluid passage; and
a gate configured to be actuated to open and close the gate valve.

6. The apparatus of claim 1, wherein the moisture trap body further comprises a vacuum flange fitting forming at least a portion of the first fluid passage.

7. The apparatus of claim 6, wherein the vacuum flange fitting is an NW, KF, or QF flange.

8. The apparatus of claim 6, further comprising a thermocouple disposed within the cavity.

9. The apparatus of claim 8, further comprising a heat source coupled to the moisture trap body.

10. The apparatus of claim 9, wherein the heat source comprises one or more resistive heating elements.

11. The apparatus of claim 1, wherein the cryogenic coil is coupled to a cryogenic fluid source.

12. A substrate processing system, comprising:
a chamber body forming an interior volume;
a substrate support disposed within the interior volume;
an exhaust opening fluidly coupled to the interior volume;
an exhaust line coupled to the exhaust opening; and
a moisture trap coupled to the exhaust line and comprising:
a body comprising:
an outer surface;
an inner surface;
a cavity formed by the inner surface; and
a first fluid passage extending from the inner surface to the exhaust line;
a cryogenic coil disposed around the moisture trap body; and
an outer casing disposed around the cryogenic coil.

13. The processing system of claim 12, further comprising a valve coupled to the outer surface, the valve further comprising a second fluid passage aligned with the first fluid passage and an exhaust line opening.

14. The processing system of claim 12, wherein the moisture trap is attached to a sidewall of the exhaust line and the first fluid passage is aligned with an exhaust line opening.

15. The processing system of claim 12, further comprising a remote plasma source.

16. The processing system of claim 12, further comprising:
a first film lining the inner surface and comprising one or a combination of a metal, a metalloid, a post-transition metal, or a metal alloy with a first thermal conductivity; and
a second film disposed on the inside of the first film, the second film having a second thermal conductivity.

17. The processing system of claim 16, further comprising
a vacuum flange fitting forming at least a portion of the first fluid passage and coupled to the valve; and
a thermocouple disposed within the cavity.

18. A method of performing maintenance on a semiconductor processing chamber, comprising:
opening a valve on a moisture trap;
exhausting one or more fluids from the semiconductor processing chamber through an exhaust line;
flowing a cryogenic fluid through a cryogenic coil within the moisture trap; and
condensing and freezing moisture from the exhaust line onto an inner surface of the moisture trap.

19. The method of claim 18, further comprising:
closing an exhaust opening or a valve on the exhaust line that is upstream of the moisture trap;
heating the moisture trap to vaporize the moisture; and
venting the vaporized moisture through an exhaust line.

20. The method of claim 18, wherein the moisture trap comprises:
a body comprising:
an outer surface;
an inner surface;
a cavity formed by the inner surface; and
a first fluid passage disposed through the outer surface to the inner surface;
a cryogenic coil disposed around the body; and
an outer casing disposed around the cryogenic coil.
